(19) United States
(12) Patent Application Publication
(10) Pub. No.: US 2007/0236978 A1
(43) Pub. Date: Oct. 11, 2007

(54) Non-volatile Reactive Magnetic Memory device (REMM)

(76) Inventor: Jannier Maximo Roiz Wilson, Oakland, CA (US)

Correspondence Address: Jannier M. Roiz, Apt. 322, 1555 Madison Street, Oakland, CA, 94612-4522, US

(21) Appl. No.: 11/398,361

(22) Filed: Apr. 6, 2006

(51) Int. Cl. G11C 11/06

(52) U.S. Cl. 365/55

(57) ABSTRACT

The present invention introduces a solid state magnetic memory concept which is based on the different inductive reactance an inductance composed of a conductor wire surrounded by magnetic material exhibits at different parts of its magnetization curve. A current pulse is used to either read or write the logic information in the bit, which is set by one of the two stable direction of circulation of the magnetic field around the conductor wire: clockwise or counter clockwise. Depending on the bit magnetization orientation there will be a larger or a smaller voltage drop across the bit, during the reading pulse. This voltage drop is also larger the faster the magnetization changes in the bit. Circuit schemes are provided for reading and addressing the bits. The proposed bit configurations are magnetically very stable and scalable.

### CROSS-REFERENCE TO RELATED APPLICATIONS

Not Applicable

### STATEMENT REGARDING FEDERALLY SPONSORED RESEARCH OR DEVELOPMENT

Not Applicable

### BACKGROUND OF THE INVENTION

1. Field of the Invention

The present invention relates to a solid state magnetic memory device, mechanisms for reading and writing information in it, and basic circuitry for reading, writing and addressing the bits along with some spatial configurations of the bits.

This invention is intended to fabricate a fast, robust, low-power, very scalable and relatively low-cost non-volatile random access memory device. In this case the non-volatility is achieved by storing the information magnetically in patterned bits. The bits are supposed to be addressed, read and written electronically. At this time there are some technologic approaches to produce memory devices with the above mentioned characteristics, which are mainly based on different bit resistance for logical states “1” and “0”. This concept however, relies on inductive reactance instead of resistance to determine the logical state in a bit. Therefore, timing is a key player in this concept. In principle, for the phenomena involved in the concept, time spans may be as short as electronically achievable.

Like other memory technologies, in this concept, the reading, writing and addressing circuitry may be semiconductor based and use the same wafer. The magnetic bits instead could be placed in superior layers.

### BRIEF SUMMARY OF THE INVENTION

The present invention introduces a solid state magnetic memory concept referred to herein as Reactive Magnetic Memory (REMM). The working principle relies on the different inductive reactance an inductance composed of a conductor wire surrounded by magnetic material exhibits in different parts of its magnetization curve. The bit is then composed of a conductor wire surrounded by magnetic material arranged in one or more pieces, depending on configuration. A current pulse is used to either read or write the logic information in the bit, which is set by one of the two writeable stable direction of magnetization perpendicular to the conductor wire. During the reading pulse, the voltage drop across the bit is a function of the inductive reactance of the bit, which is smaller if the bit goes from a closely to a more closely saturated magnetization (due to the magnetic field induced by the current in the conductor wire) than when the magnetization varies widely away from saturation. Therefore, during the reading pulse, depending on the orientation of the bit magnetization the bit will exhibit a larger or a smaller voltage drop across itself. This voltage drop is also larger the faster the magnetization changes in the bits. Hence, for this concept, faster is better. The bits of a byte, in one end, may share a common line which electrically connects to ground potential after passing through a transistor. This transistor selects the byte or group of bytes, depending on configuration, to be addressed. A row of transistors uniquely wired are the responsible for addressing this ground-connecting transistor. On the other end, each bit may be connected to a data line where the direction and the magnitude of the current passing through the bit are set. The magnetization around the inner conductor of the bit makes the bit magnetically very stable and favors high storage density.

### BRIEF DESCRIPTION OF THE DRAWINGS

FIG. 1 Schematic representation of the magnetization curve of magnetic material in a bit. M represents the magnetization in the direction of the current-induced magnetic field and H the current-induced magnetic field. Initially the system may be at the points 1 or 3 and then due to an applied external field it goes to the corresponding points 2 or 4 and back. The corresponding variation of magnetization is very different in each case.

FIG. 2 Illustration of the plan 7 and perspective 8 views of a possible bit configuration. The magnetic material 6 surrounds a conductor 5.

FIG. 3 Illustration of bits, as proposed in FIG. 2. The magnetic material is circularly magnetized in the planes parallel to the figure, after set by the writing current. Bit information “1” or “0” is set by the direction of circulation of the magnetic field: clockwise or counter clockwise, as indicated by the arrows 9.

FIG. 4 Schematic representation of the wiring of the reading circuit.

FIG. 5 Two geometrical variations of the bit. The bits are conformed by four magnetic pieces placed around a conductor. Arrows point at the direction of magnetization in the corresponding magnetic piece.

FIG. 6 Schematic representation of a meaningful part of a circuit for addressing the bytes. A row of FET transistors 17, addressed through the lines A0, A1, A2, . . . , are responsible for opening a more current-resistant transistor 19 that connects the byte (through contacts 20) to ground potential. Each addressing line (A0, A1, A2, . . . ) is divided in two lines, one of which is logically negated by a NOT gate 18. Transistors 17 are connected to one of these lines depending on the byte address.

FIG. 7 Schematic representation of the storing layer. Bits 21 are connected from above with the data lines 24 and from below with the connecting lines 22. The contacts 23 connect with ground potential through the addressing mechanism below.

FIG. 8 Other bit configurations and more efficient spatial distributions.

FIG. 9 A bit 30 may be divided in two smaller parts 31 to increase the magnetic stability of “1” and “0”. In the FIG. 32 and 29 represent the inner conductor and the magnetic material surrounding the conductor, respectively.

### DETAILED DESCRIPTION OF THE INVENTION

1. Working principle

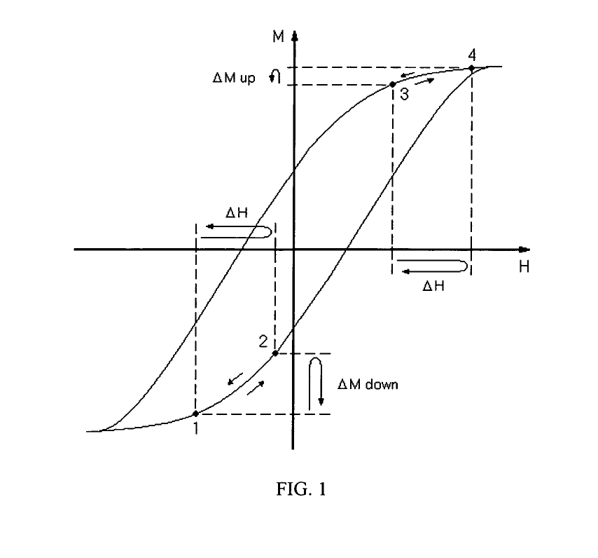

The principle is to sense the different inductive reactance in an inductance composed of a conductor wire surrounded by shaped magnetic material when the system is placed in different parts of its hysteresis loop. The inductive reactance depends on the slope of the magnetization curve. When a varying magnetic field is induced by a current pulse in the conductor wire; if the magnetic material in the bit is magnetized close to saturation, and the induced magnetic field takes the system even closer to saturation, the inductive reactance is lower than when the magnetic material is magnetized in the opposite direction and the induced magnetic field takes the system away from saturation. Subsequently, the logical information “1” or “0” is set depending on the orientation of magnetization. In FIG. 1 two possible reading zones (1-2 and 3-4) in a schematic representation of a hysteresis loop are depicted. Each zone corresponds to the reading of either a “1” or a “0”. For reading, the system in FIG. 1 goes from point 1 to point 2 and back or from point 3 to point 4 and back, depending on initial magnetization. The corresponding variation in bit magnetization ΔM down is considerably larger than ΔM up. The magnetic material may be either multi or single domain, what is important is the rate of variation of the magnetic flux around the conductor. Magnetization at points 1 and point 3 may already be saturated but the working principle would still be the same.

The writing mechanism uses an electric current, flowing through the mentioned conductor, large enough to produce the inversion of the direction of magnetization in the magnetic material surrounding the conductor.

2. In more detail

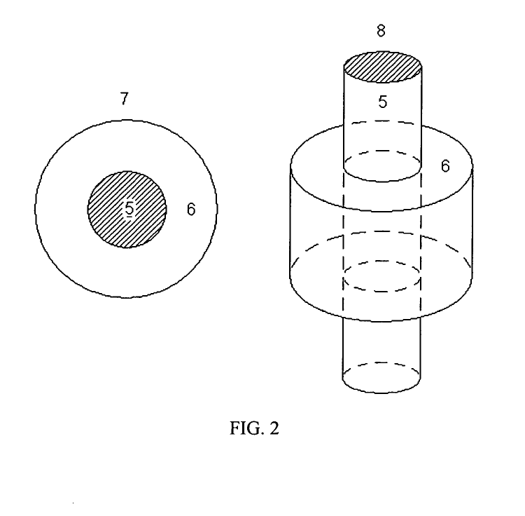

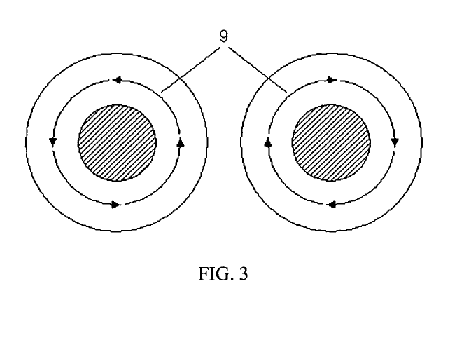

A schematic representation of a possible structure of a bit is shown in FIG. 2, where there is a conductor 5 in the middle, and magnetic material 6 surrounding the conductor. The magnetic material gets circularly magnetized normal to the current density that eventually flows through the conductor, as shown in FIG. 3. The thoroidal shape of the magnetic piece allows the bit to have two very stable circular magnetizations: clockwise and counter clockwise. In this configuration, the magnetic field generated by the bit cancel out partially away from the bit, which works in favour of higher bit density.

To lower energy consumption and increase storage density the size of the bit should be lowered, especially in the radial direction. The magnetic stability of this configuration makes the bit very scalable.

3. Reading mechanism

Reading may be done by letting a current pulse passing through the conductor of the bit. The current variation di/dt in the conductor, due to the pulse, generates a varying magnetic field in and around the bit that in terms generates an electric field that interacts with the pulse. The voltage difference induced in the bit is equal to menus the rate of variation in time of the magnetic flux around the bit. Therefore, the faster the magnetization changes in the bit, the larger is the voltage difference between both ends of the bit. This means that increasing the rate of variation of the current in the bit (di/dt) increases the voltage difference across the bit.

When the induced magnetic field and the magnetization in the magnetic material are closely aligned in the same direction and sense, the bit inductance goes to a minimum, as the magnetic material approaches saturation and therefore the magnetization has relatively little variation. Instead, when they are anti-aligned, the bit inductance is much larger, as the magnetic material deviates away from saturation and the magnetization has comparatively significant variation.

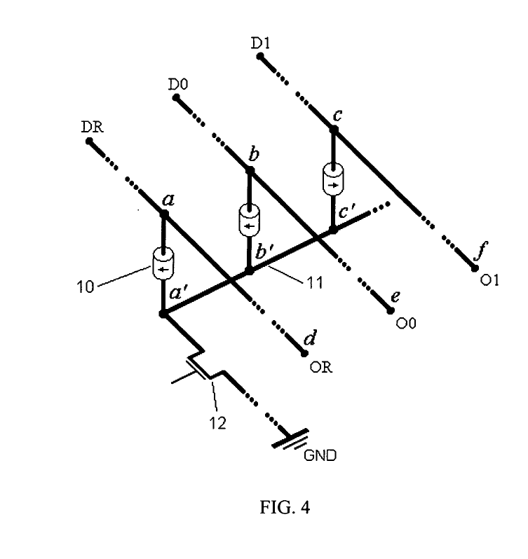

One way to identify the bits information of a particular byte through its inductance is to compare the voltage drop across the bits during the pulse duration. The current pulse should flow simultaneously in all the bits of an addressed byte in the same direction and sense. The basic circuit exemplified with three adjacent bits of a byte is shown in FIG. 4. One extra bit of the byte is left for reference. This extra bit will always have the same polarization (“1” or “0”), the one that would not get the magnetization flipped during reading. In FIG. 4 the reading signal should be placed simultaneously at the points DR, D0 and D1 and the output should be taken from points OR, O0 and O1. DR and OR are for reference. The arrows in the bits 10 point the direction of magnetization at a middle point in the surface of the bit. The wire 11 connecting points a′, b′ and c′ (connecting line) leads to ground potential. The transistor 12 controls the addressing of the byte.

The resistance of the wires connecting a bit should be virtually the same for each bit in a particular byte (wires with the same quality and dimensions). In an actual memory configuration, the wire 11 connecting points a′, b′ and c′ should be relatively thick and very small compared to the other wires leading to the bits. So, this wire should not introduce any substantial resistance. Therefore, during the pulse duration, the voltage in the points a′, b′ and c′ is equal and then the voltage difference between the points a and b (Vb−Va) and a and c (Vc−Va) is the difference of voltage drop in the bits. The voltage difference between the points a, b and c can also be sensed at the points d, e and f (Vb−Va=Ve−Vd and Vc−Va=Vf−Vd). Also, the resistance of the wires connecting the bit should be very large compare to the inductive reactance in the bit. Therefore the current passing through every bit of a byte, during reading, is virtually the same and the voltage drop due to the relatively small resistance of the inner conductor of the bit is also the same. So, the difference in voltage drop between different bits of a byte is dominated by the inductive reactance of the bits. As the voltage drop in the bit is proportional to the bit inductance, the voltage difference for two bits with opposed magnetization (at a given time) should be appreciably larger than for two bits with similar magnetization (Ve−Vd<<Vf−Vd). Those differences can be used to identify the bits information.

For reading, the bits with magnetization contrary to the current-induced field may be chosen to flip or not during the reading pulse. Flipping the bit magnetization during reading makes the response of the bit larger and allows more freedom with the magnetization curve but also has a cost in reading time and energy requirements, mainly because the bits must be flipped back. However, as bits dimensions get smaller this approach gains attractiveness, as lower dimensions may also reduce energy requirements and reading time.

Another approach to sense the bit inductive reactance may be through an RLC circuit. In this case the circuit connecting each bit must have a resistance and a capacitance that guarantee the reading time to be in the appropriate time range. As the time response of this RLC circuit depends on inductance, the variation in time of the voltage on a given part of the circuit depends on the bit magnetization direction, which may be used to identify the bit information. This reading approach allows decreasing the bit inductance (due to down-size scaling) while compensating with increasing the RLC circuit capacitance, so that the RLC circuit response remains nearly the same. The current flow through the bit may or may not be chosen to be large enough to switch the bits with opposed magnetization during reading.

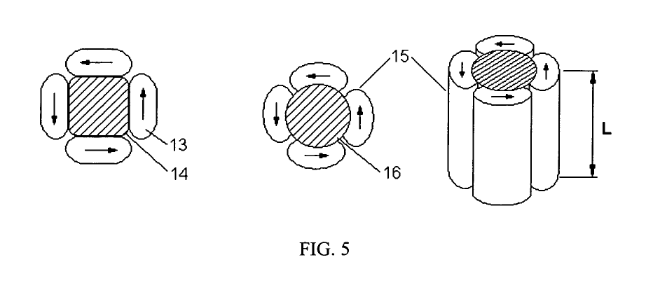

The bit may have different shapes and be formed by several magnetic pieces. Examples of such geometrical variations are shown in FIG. 5, where four magnetic pieces 13 and 15 in FIG. 5 surround a conductor 14 and 16. The high aspect ratio of the magnetic pieces should allow an easy axis of magnetization to be approximately in the direction of the arrows in FIG. 5. Several magnetic pieces surrounding the conductor as in FIG. 5, although is not crucial to the working principle, is to increase thermal stability of the bit and to reduce the intensity of the magnetic field away from the bit (to allow higher storage density). Also, in case of the magnetic pieces being multiple domains, several magnetic pieces allow the bit to be magnetized closer to saturation. In case of the magnetic pieces being single domain, several pieces are not crucial but may be used to improve performance. The vertical length of the bit (L in FIG. 5), the shape and size of the magnetic pieces, the magnetic material used in each piece and the conductor radius are very important parameters to adjust bit inductance and bit stability.

4. Writing mechanism

For flipping the bit, an electrical current should be made to flow through the conductor. The current must flow in the proper direction and be large enough as to produce the inversion of the direction of magnetization in the magnetic material around the conductor, in bits with magnetization opposing the current-induced magnetic field.

5. More ideas specific to a memory storing device

A possible storing device may consist of a multilayered structure. In one layer goes the addressing mechanism, then a layer holding the connecting lines 11, on top of it a layer holding the bits and on top a layer with the data lines (read-write lines). The bits may be distributed in hexagonal-pack configuration to accommodate the largest number of bits per area unit. Each mentioned layer may have several layers itself in order to accommodate all its elements.

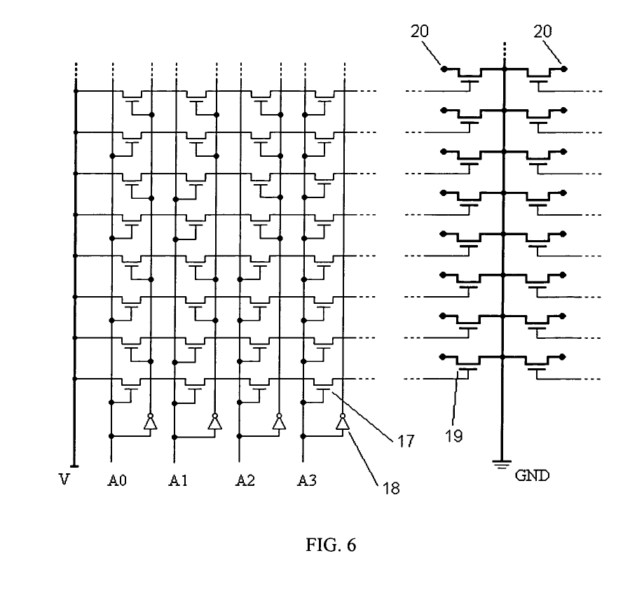

The byte addressing mechanism may consist of arrays of FET transistors as shown in FIG. 6. Each byte has a unique row of transistors uniquely wired. To address a particular byte, through contacts 20 in FIG. 6, the row of transistors leading to that byte opens a current-resistant transistor 19 responsible for connecting the ground line to that byte.

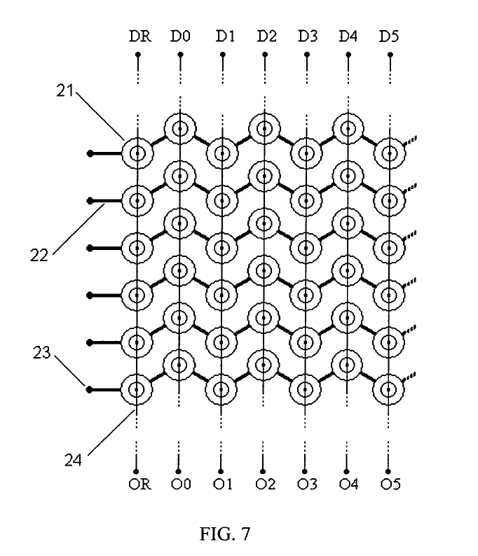

Data lines 24 connect the bits from above and connecting lines 22 connect the bits from below as suggested in FIG. 7. Writing “0” or “1” implies applying positive or negative voltages in the data lines. If positive and negative voltages are put simultaneously in different data lines, numerous unaddressed bits would be exposed to a large voltage difference. To prevent significant currents from passing through bytes different than the one addressed (the one connected to ground potential), writing can be done in two stages. In one stage, only “1s” are written and “0s” are written in the other stage, or vice versa. The same data lines must be used for reading. The reading and writing circuits may be common to all bytes and be located in one end of the data lines. The R&W circuitry and all the transistors may be built on the same wafer.

If necessary, there may be several bytes on top of every addressing transistors array, enough to cover the extent of any large set of address lines. These bytes would share the connecting line 22, the reference bit and the addressing transistors 19, but they may be addressed individually through their corresponding data lines. In this way, the bits may efficiently occupy the bits layer space regardless of the space needed to accommodate the addressing mechanism below.

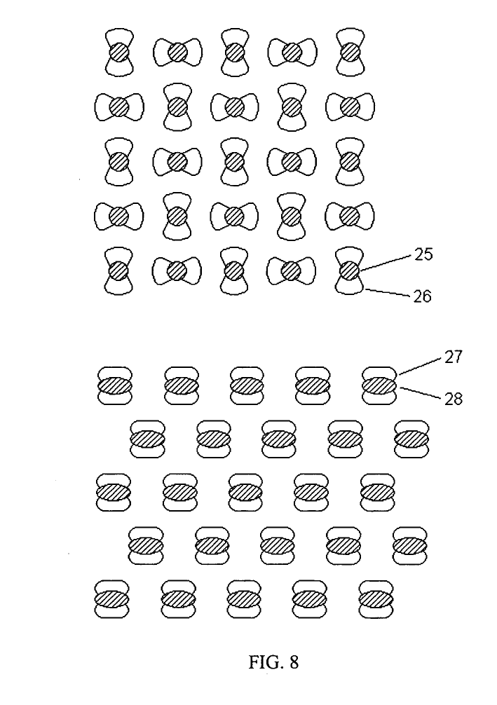

One way to increase bits density is to change the shape of the bit and spatial distribution. Provided the response of the bit is strong enough, some magnetic pieces (of the multi-pieces bit) may be removed and the bits accommodated in more spatially efficient ways. Two of such distributions are shown in FIG. 8. In the figure, the bits consist of a conductor (25 and 28) sandwiched by two magnetic pieces (26 and 27).

5.1. Downsizing

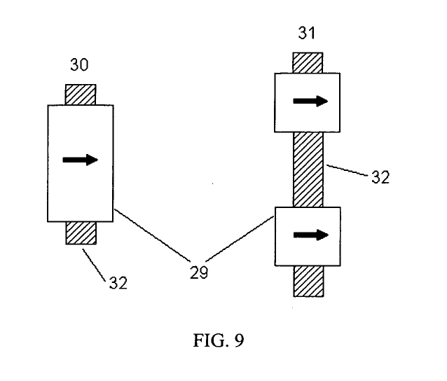

To maintain high the bit inductance and magnetic stability of “1” and “0” while downsizing the bit area, the bit could be divided in smaller sections, as shown in FIG. 9. These sections should be positioned apart enough so they do not interact significantly with each other. In this way the bit magnetization is less likely to go vertical, as the aspect ratio of the bit radius/height is kept high.

5.2.3D Memory Storage

Storing density may be increased by stacking several storing layers (connecting lines+bits layer+data lines) on top of the first storing layer. These storing layers may share the addressing mechanism which would be connected to the vertically stacked bytes through a vertical wire which would connect the connecting lines 22 of the bytes, running from contact 20 to contact 23 of each storing layer. Different storing layers should be then addressed through their corresponding data lines.

What is claimed is:

1. A non-volatile solid state magnetic memory device concept, wherein the bit is an inductance composed of a conductor wire surrounded by magnetic and in which the binary information is set by the direction of circulation of the magnetic field around the conductor of the bit.

2. The bits according to claim 1, wherein the inductive reactance is different depending on how the magnetic dipole moments are distributed in the magnetic material of the bit, when a varying current is applied to the conductor of the bit.

3. The bits according to claim 1, wherein the shape and the number of magnetic pieces around the conductor may be changed in innumerable ways, some of which are shown herein.

4. A mechanism for reading the byte, wherein one bit is left for reference to compare the voltage drop in the other bits with.

5. A byte addressing mechanism, wherein an array of transistors uniquely wired, when addressed, open the channel of a high current-resistant transistor which connects the byte to ground potential.
